(19) United States
(12) Patent Application Publication
(10) Pub. No.: US 2005/0224336 A1
(43) Pub. Date: Oct. 13, 2005

(54) Core insert for glass molding machine and method for making same

(75) Inventor: Ga-Lane Chen, Fremont, CA (US)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-cheng City (TW)

(21) Appl. No.: 11/089,861

(22) Filed: Mar. 25, 2005

(30) Foreign Application Priority Data
Apr. 9, 2004 (TW) 93109881

(51) Int. Cl. C23C 14/32

(52) U.S. Cl. 204/192.16; 204/192.15

(57) ABSTRACT

A core insert for a glass molding machine includes a substrate, an adhesive layer, and a protective film. The substrate is made of tungsten carbide. The adhesive layer is deposited on a surface of the substrate, and the adhesive layer is made of amorphous C:H. The protective film is deposited on a surface of the adhesive layer. The core insert has good adhesion between the substrate and the protective film because of the adhesive layer, and thus has a long working lifetime. A method for making the core insert is also provided.

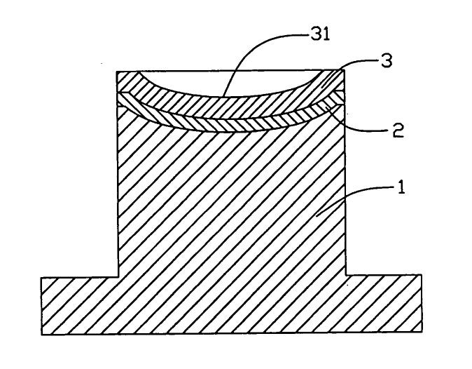

### BACKGROUND OF THE INVENTION

1. Field of the Invention

The present invention generally relates to glass molding machines, and more particularly to a core insert for a glass molding machine.

2. Prior Art

Currently, digital camera modules are included as a feature in a wide variety of portable electronic devices. Most portable electronic devices are becoming progressively more miniaturized over time, and digital camera modules are correspondingly becoming smaller and smaller. Nevertheless, in spite of the small size of a contemporary digital camera module, consumers still demand excellent imaging. Image quality of a digital camera is mainly dependent upon the optical elements of the digital camera module.

Aspheric lenses are very important elements in the digital camera module. Contemporary aspheric lenses are manufactured by way of glass molding. The glass molding machine operates at a high temperature and high pressure during the glass molding process. Therefore, core inserts are needed, and must be accurately designed and manufactured. The core inserts should have excellent chemical stability in order not to react with the glass material. In addition, the core inserts also should have enough rigidity and excellent mechanical strength in order not to be scratched. Furthermore, the core inserts should be impact-resistant at high temperatures and high pressures. Moreover, the core inserts must have excellent machinability, in order for them to be machined precisely and easily to form the desired optical surfaces. Finally, the core inserts must have a long working lifetime so that the cost of manufacturing aspheric lenses is reduced.

A typical contemporary core insert comprises a substrate and a protective film. The substrate is made of stainless steel, carborundum (SiC), or tungsten carbide (WC). The protective film is made of diamond-like carbon film (DLC), noble metals, or alloys of noble metals. The noble metals can be platinum (Pt), iridium (Ir) or ruthenium (Ru). The alloys of noble metals can be iridium-ruthenium (Ir-Ru), platinum-iridium (Pt-Ir), or iridium-rhenium (Ir-Re). The diamond-like carbon film has a short working lifetime. The noble metals or alloys of noble metals have good chemical stability, rigidity and heat-resistance. Nevertheless, the protective film made of noble metals or alloys of noble metals has poor adhesion with the substrate. Thus the core insert generally has a short working lifetime, which escalates the cost of producing aspheric lenses.

Therefore, a core insert for a glass molding machine which overcomes the above-described problems is desired.

### SUMMARY OF THE INVENTION

Accordingly, an object of the present invention is to provide a core insert which has good adhesion between a substrate and a protective film thereof, and which has a long working lifetime.

Another object of the present invention is to provide a method for making the above-described core insert.

To achieve the first of the above objects, a core insert for a glass molding machine comprises a substrate, an adhesive layer, and a protective film. The substrate is made of tungsten carbide. The adhesive layer is deposited on a surface of the substrate, and the adhesive layer is made of amorphous C:H. The protective film is deposited on a surface of the adhesive layer. The core insert has good adhesion between the substrate and the protective film because of the adhesive layer, and thus has a long working lifetime.

To achieve the second of the above objects, a method for making a core insert comprises the steps of: providing a substrate, the substrate being made of tungsten carbide; depositing an adhesive layer on a surface of the substrate, the adhesive layer being made of amorphous C:H; and depositing a protective film on a surface of the adhesive film. The adhesive layer can be deposited by way of reactive sputtering.

Other objects, advantages and novel features of the invention will become more apparent from the following detailed description when taken in conjunction with the accompanying drawing, in which:

### BRIEF DESCRIPTION OF THE DRAWINGS

The drawing is a cross-sectional view of a core insert in accordance with a preferred embodiment of the present invention.

### DETAILED DESCRIPTION OF THE INVENTION

Referring to the drawing, in a first preferred embodiment, a core insert comprises a substrate 1, an adhesive layer 2, and a protective film 3. The adhesive layer 2 is deposited on the surface of the substrate 1, and the protective film 3 is deposited on the surface of the adhesive layer 2. The protective film 3 has a concave surface 31. The substrate 1 is made of tungsten carbide, the adhesive layer 2 is made of amorphous C:H, and the protective film 3 is made of carborundum or an alloy of platinum-iridium.

A method of making the core insert comprises the steps of: providing a substrate 1 made of tungsten carbide; depositing an adhesive layer 2 on a surface of the substrate 1, the adhesive layer 2 being made of amorphous C:H; and depositing a protective film 3 on a surface of the adhesive layer 2. The amorphous C:H can be deposited on the substrate 1 by way of reactive sputtering, such as DC reactive sputtering, AC reactive sputtering, or RF (radio frequency) reactive sputtering. The sputtering gas is argon with methane or ethane. The adhesive layer 2 is preferably 2-8 nm thick.

When the protective film 3 is made of carborundum, the protective film 3 can be deposited by way of RF reactive sputtering. The sputtering gas can be methane with argon or krypton, or hydrogen with argon or krypton. The proportion of methane or hydrogen in the sputtering gas is 5-20%. The sputtering frequency is 13.56 MHz. The protective film 3 is preferably 20-100 nm thick.

When the protective film 3 is made of platinum-iridium, the protective film 3 can be deposited by way of DC magnetron sputtering or RF sputtering. The protective film 3 is preferably 20-100 nm thick.

In a second preferred embodiment, a core insert comprises a substrate 1, an adhesive layer 2, and a protective film 3. The substrate 1 is made of carborundum, the adhesive layer 2 is made of silicon, and the protective film 3 is made of carborundum or an alloy of platinum-iridium.

A method of making the core insert of the second embodiment comprises the steps of: providing a substrate 1, the substrate 1 being made of carborundum; depositing an adhesive layer 2 on a surface of the substrate 1, the adhesive layer 2 being made of silicon; and depositing a protective film 3 on a surface of the adhesive layer 2. The silicon is deposited on the substrate 1 by way of AC sputtering, RF sputtering, or chemical vapor deposition. The adhesive layer 2 is preferably 2-8 nm thick.

The protective film 3 is deposited by employing the same method as in the first embodiment, wherein the protective film 3 being made of carborundum or an alloy of platinum-iridium.

In a third preferred embodiment, a core insert comprises a substrate 1, an adhesive layer 2, and a protective film 3. The substrate 1 is made of silicon nitride, the adhesive layer 2 is made of silicon, and the protective film 3 is made of silicon nitride or an alloy of platinum-iridium.

A method of making the core insert of the third embodiment comprises the steps of: providing a substrate 1, the substrate 1 being made of silicon nitride; depositing an adhesive layer 2 on a surface of the substrate 1, the adhesive layer 2 being made of silicon; and depositing a protective film 3 on a surface of the adhesive layer 2. The silicon is deposited on the substrate 1 by way of AC sputtering, RF sputtering, or chemical vapor deposition. The adhesive layer 2 is preferably 2-8 nm thick.

When the protective film 3 is made of silicon nitride, the protective film 3 can be deposited by way of DC reactive sputtering. The sputtering gas can be argon with nitrogen. The protective film 3 is preferably 20-100 nm thick. When the protective film 3 is made of platinum-iridium, the protective film 3 can be deposited by employing the same method as in the first embodiment.

In a fourth preferred embodiment, a core insert comprises a substrate 1, an adhesive layer 2, and a protective film 3. The substrate 1 is made of boron nitride carbide (BNC), the adhesive layer 2 is made of amorphous C:N, and the protective film 3 is made of boron nitride carbide (BNC) or alloy of platinum-iridium.

A method of making the core insert of the fourth embodiment comprises the steps of: providing a substrate 1, the substrate 1 being made of boron nitride carbide (BNC); depositing an adhesive layer 2 on a surface of the substrate 1, the adhesive layer 2 being made of amorphous C:N; and depositing a protective film 3 on a surface of the adhesive layer 2. The amorphous C:N is deposited on the substrate 1 by way of reactive sputtering, such as DC reactive sputtering, AC reactive sputtering, or RF reactive sputtering. The sputtering target is graphite, and the sputtering gas is argon with nitrogen. The adhesive layer 2 is preferably 2-8 nm thick.

When the protective film 3 is made of boron nitride carbide (BNC), the protective film 3 can be deposited by way of reactive sputtering, such as DC reactive sputtering, AC reactive sputtering or RF reactive sputtering. The sputtering gas can be argon with nitrogen. When the protective film 3 is made of platinum-iridium, the protective film 3 can be deposited by employing the same method as in the first embodiment. The protective film 3 is preferably 20-100 nm thick.

As an adhesive layer, the amorphous C:H, silicon or amorphous C:N can enhance the adhesion between the substrate 1 and the protective film 3. The core insert can be use to manufacture aspheric lenses more than 10,000 times.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A method for making a core insert, comprising the steps of:
providing a substrate, the substrate being made of tungsten carbide;
depositing an adhesive layer on a surface of the substrate, a material of the adhesive layer being amorphous C:H; and
depositing a protective film on a surface of the adhesive layer;
wherein the amorphous C:H is deposited by way of reactive sputtering, the sputtering gas being argon with methane or ethane.

2. The method according to claim 1, wherein said reactive sputtering is DC reactive sputtering, AC reactive sputtering, or RF (radio frequency) reactive sputtering.

3. The method according to claim 1, wherein the protective film is made of carborundum, and the protective film is deposited by way of RF (radio frequency) reactive sputtering.

4. The method according to claim 3, wherein the sputtering target is carborundum, and the sputtering gas is selected from the group consisting of methane with argon, methane with krypton, hydrogen with argon, and hydrogen with krypton.

5. The method according to claim 1, wherein the protective film is made of an alloy of platinum-iridium, and the protective film is deposited by way of DC magnetron sputtering or RF (radio frequency) sputtering.

6. The method according to claim 1, wherein the adhesive layer is 2-8 nm thick.

7. The method according to claim 1, wherein the protective film is 20-100 nm thick.

8. A method for making a core insert, comprising the steps of:
providing a substrate, the substrate being made of silicon nitride;
depositing an adhesive layer on a surface of the substrate, the adhesive being made of silicon; and
depositing a protective film on a surface of the adhesive layer.

9. The method according to claim 8, wherein the silicon is deposited by way of AC sputtering, RF (radio frequency) sputtering, or chemical vapor deposition.

10. The method according to claim 8, wherein the protective film is made of silicon nitride, and the protective film is deposited by way of DC reactive sputtering or RF (radio frequency) reactive sputtering.

11. The method according to claim 10, wherein the sputtering target is silicon nitride, and the sputtering gas is argon with nitrogen.

12. The method according to claim 8, wherein the protective film is made of an alloy of platinum-iridium, and the protective film is deposited by way of DC magnetron sputtering or RF sputtering.

13. The method according to claim 8, wherein the adhesive layer is 2-8 nm thick.

14. The method according to claim 8, wherein the protective film is 20-100 nm thick.

15. A method for making a core insert, comprising the steps of:
providing a substrate, the substrate being made of boron nitride carbide (BNC);
depositing an adhesive layer on a surface of the substrate, the adhesive being made of amorphous C:N; and
depositing a protective film on a surface of the adhesive layer;
wherein the amorphous C:N is deposited by way of reactive sputtering, the sputtering target is graphite, and the sputtering gas is argon with nitride.

16. The method according to claim 15, wherein the reactive sputtering is DC reactive sputtering, AC reactive sputtering or RF (radio frequency) reactive sputtering.

17. The method according to claim 15, wherein the protective film is made of boron nitride carbide (BNC), the protective film is deposited by way of reactive sputtering, and the sputtering gas is argon with nitrogen.

18. The method according to claim 15, wherein the protective film is made of an alloy of platinum-iridium, and the protective film is deposited by way of DC magnetron sputtering or RF (radio frequency) sputtering.

19. The method according to claim 15, wherein the adhesive layer is 2-8 nm thick.

20. The method according to claim 15, wherein the protective film is 20-100 nm thick.
